(19) United States
(12) Patent Application Publication
(10) Pub. No.: US 2025/0157908 A1
(43) Pub. Date: May 15, 2025

(54) SEMICONDUCTOR PACKAGE

(71) Applicant: SAMSUNG ELECTRONICS CO., LTD., Suwon-si (KR)

(72) Inventors: Hyuekjae Lee, Suwon-si (KR); Jinkyeong Seol, Suwon-si (KR)

(73) Assignee: SAMSUNG ELECTRONICS CO., LTD., Suwon-si (KR)

(21) Appl. No.: 18/768,919

(22) Filed: Jul. 10, 2024

(30) Foreign Application Priority Data
Nov. 10, 2023 (KR) 10-2023-0155026

(51) Int. Cl. H01L 23/498; H01L 23/00; H01L 23/29; H01L 23/31; H01L 23/48; H01L 25/18; H10B 80/00

(52) U.S. Cl. CPC H01L 23/49838; H01L 23/291; H01L 23/3135; H01L 23/3142; H01L 23/481; H01L 23/49822; H01L 24/04; H01L 24/08; H01L 25/18; H01L 2224/0401; H01L 2224/08145; H01L 2224/08235; H01L 2924/1431; H01L 2924/1436; H10B 80/00

(57) ABSTRACT

Provided is a semiconductor package, including a first semiconductor chip including a plurality of first through-electrodes, a second semiconductor chip including a plurality of second through-electrodes, at least one third semiconductor chip including a plurality of third through-electrodes, a plurality of first through-vias electrically connected to a second group of first rear pads, a plurality of second through-vias electrically connected to the plurality of first through-vias, and tapered toward the plurality of first through-vias, and a plurality of connection bumps electrically connected to the plurality of third rear pads and the plurality of second through-vias, wherein a maximum diameter of the plurality of second through-vias is larger than a maximum diameter of the plurality of first through-vias in a horizontal direction.

### CROSS-REFERENCE TO RELATED APPLICATION

This application claims priority to Korean Patent Application No. 10-2023-0155026 filed on Nov. 10, 2023, in the Korean Intellectual Property Office, the disclosure of which is incorporated herein by reference in its entirety.

### BACKGROUND

Embodiments of the present disclosure relate to a semiconductor package.

A semiconductor package mounted on an electronic device requires miniaturization, high performance, and high capacitance. In order to implement miniaturization, high performance, and high capacitance, research and development of a semiconductor package in which semiconductor chips including through-silicon vias (TSV) are stacked in a vertical direction have been conducted.

### SUMMARY

One or more embodiments provide a semiconductor package having improved voltage characteristics.

According to an aspect of one or more embodiments, there is provided a semiconductor package, including a first semiconductor chip including a first integrated circuit on a first front surface, a plurality of first rear pads on a first rear surface opposite to the first front surface, and a plurality of first through-electrodes electrically connecting the first integrated circuit and the plurality of first rear pads, the plurality of first rear pads including a first group of first rear pads and a second group of first rear pads, a second semiconductor chip including a second integrated circuit on a second front surface facing the first rear surface of the first semiconductor chip, a plurality of first front pads electrically connected to the second integrated circuit and in contact with the first group of first rear pads, a plurality of second rear pads on a second rear surface opposite to the second front surface, and a plurality of second through-electrodes electrically connecting the second integrated circuit and the plurality of second rear pads, a first sealing layer on the second front surface and a side surface of the second semiconductor chip, at least one third semiconductor chip including a third integrated circuit on a third front surface facing the second rear surface of the second semiconductor chip, a plurality of second front pads electrically connected to the third integrated circuit and in contact with the plurality of second rear pads, a plurality of third rear pads on a third rear surface opposite to the third front surface, and a plurality of third through-electrodes electrically connecting the third integrated circuit and the plurality of third rear pads, a second sealing layer on the third rear surface and a side surface of the at least one third semiconductor chip, a plurality of first through-vias penetrating through the first sealing layer and electrically connected to the second group of first rear pads, a plurality of second through-vias penetrating through the second sealing layer, electrically connected to the plurality of first through-vias, the plurality of second through-vias having a shape tapered toward the plurality of first through-vias, and a plurality of connection bumps on the second sealing layer, and electrically connected to the plurality of third rear pads and the plurality of second through-vias, wherein a maximum diameter of the plurality of second through-vias is greater than a maximum diameter of the plurality of first through-vias in a horizontal direction.

According to another aspect of one or more embodiments, there is provided a semiconductor package, including a first semiconductor chip including a first substrate having a first front surface and a first rear surface opposite to each other, a plurality of first rear pads on the first rear surface, a first passivation layer on at least a portion of each of the plurality of first rear pads, and a plurality of first through-electrodes penetrating through the first substrate and electrically connected to the plurality of first rear pads, a second semiconductor chip including a second substrate having a second front surface and a second rear surface opposite to each other, a plurality of first front pads on the second front surface and in contact with the plurality of first rear pads, a plurality of second rear pads on the second rear surface, a second passivation layer on at least a portion of each of the plurality of second rear pads, and a plurality of second through-electrodes penetrating through the second substrate and electrically connected to the plurality of second rear pads, a first sealing layer including a gap-fill portion on a side surface of the second semiconductor chip and at least a portion of each of the plurality of first front pads, and a passivation portion on the gap-fill portion and in contact with the first passivation layer, at least one third semiconductor chip including a third substrate having a third front surface and a third rear surface opposite to each other, a plurality of second front pads on the third front surface and in contact with the plurality of second rear pads, a third passivation layer on at least a portion of each of the plurality of second front pads and in contact with the second passivation layer, a plurality of third rear pads on the third rear surface, and a plurality of third through-electrodes penetrating through the third substrate and electrically connected to the plurality of third rear pads, a second sealing layer on a side surface of the at least one third semiconductor chip, and on at least a portion of each of the plurality of third rear pads, a plurality of first through-vias penetrating through the first sealing layer and electrically connected to at least some of the plurality of first rear pads, a plurality of second through-vias penetrating through the second sealing layer and electrically connected to the plurality of first through-vias, and a plurality of connection bumps on the plurality of third rear pads and the plurality of second through-vias, wherein a material of the first sealing layer is different from a material of the second sealing layer.

According to still another aspect of one or more embodiments, there is provided a semiconductor package, including a first semiconductor chip including a plurality of first rear pads, and a plurality of first through-electrodes electrically connected to the plurality of first rear pads, a second semiconductor chip including a plurality of first front pads in contact with the plurality of first rear pads, a plurality of second rear pads, and a plurality of second through-electrodes electrically connected to the plurality of second rear pads, at least one third semiconductor chip including a plurality of second front pads in contact with the plurality of second rear pads, a plurality of third rear pads, and a plurality of third through-electrodes electrically connected to the plurality of third rear pads, a plurality of first through-vias on at least one side of the second semiconductor chip and electrically connected to at least some of the plurality of first rear pads, a plurality of second through-vias on at least one side of the at least one third semiconductor chip and electrically connected to the plurality of first through-vias, and a plurality of connection bumps on the plurality of third rear pads and the plurality of second through-vias, wherein the first semiconductor chip is configured to receive power through the plurality of first through-vias and the plurality of second through-vias, and wherein the second semiconductor chip is configured to receive power through the plurality of third through-electrodes of the at least one third semiconductor chip.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a plan view illustrating a semiconductor package according to one or more embodiments;

FIG. 2A is a cross-sectional view taken along the line I-I′ of FIG. 1, and FIG. 2B is a partially enlarged view of region ‘A’ of FIG. 2A;

FIG. 3 is a cross-sectional view of a semiconductor package according to one or more embodiments;

FIG. 4 is a cross-sectional view of a semiconductor package according to one or more embodiments;

FIGS. 5A, 5B, 5C, 5D, 5E, 5F, 5G, 5H, 5I, 5J, 5K, and 5L are views illustrating a method of manufacturing the semiconductor package of FIG. 1;

FIG. 6 is a cross-sectional view of a semiconductor package according to one or more embodiments;

FIG. 7 is a cross-sectional view of a semiconductor package according to one or more embodiments; and

FIG. 8A is a plan view illustrating a semiconductor package according to one or more embodiments, and FIG. 8B is a cross-sectional view taken along line II-II′ of FIG. 8A.

### DETAILED DESCRIPTION

Hereinafter, embodiments of the present disclosure will be described with reference to the accompanying drawings. Embodiments described herein are example embodiments, and thus, the disclosure is not limited thereto.

Hereinafter, embodiments of the present disclosure will be described with reference to the accompanying drawings. Unless otherwise specified, in the present specification, it may be understood that the expressions such as “on,” “above,” “upper,” “below”, “beneath,” “lower,” and “side,” merely indicated based on drawings, and may actually vary depending on the direction in which the components are disposed. It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

In order to distinguish various elements, steps and directions from each other, ordinal numbers such as “first,” “second,” “third,” etc. may be used as labels such as specific elements, steps, and directions, terms not described using “first,” “second,” etc. in the specification may still be referred to as “first” or “second” in the claim. In addition, terms referred to as specific ordinal numbers (e.g., “first” in certain claims) may be described as different ordinal numbers (e.g., “second” in specifications or other claims) elsewhere.

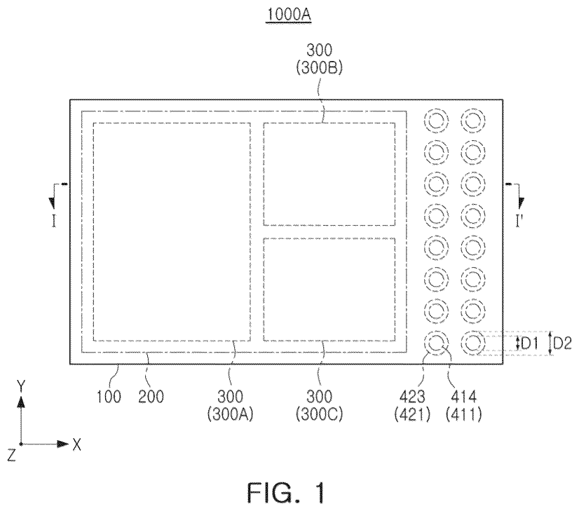

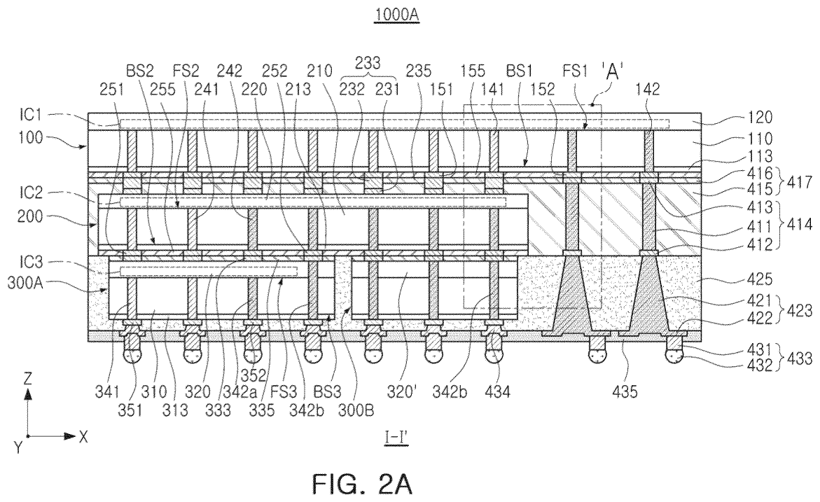

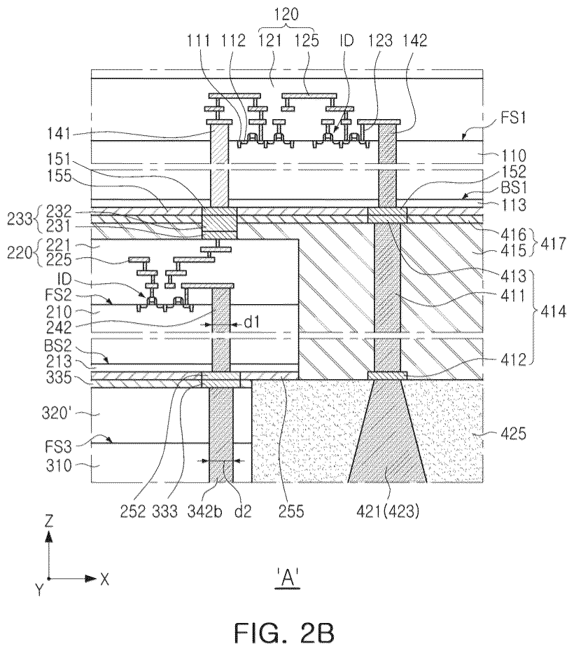

FIG. 1 is a plan view illustrating a semiconductor package 1000 according to one or more embodiments, and FIG. 2A is a cross-sectional view taken along the line I-I′ of FIG. 1, and FIG. 2B is a partially enlarged view of region ‘A’ of FIG. 2A.

Referring to FIGS. 1, 2A and 2B, a semiconductor package 1000A may include a plurality of semiconductor chips 100, 200, and 300 stacked in a vertical direction (Z-direction), for example, a first semiconductor chip 100, a second semiconductor chip 200, and at least one third semiconductor chip 300. Furthermore, the semiconductor package 1000A may further include a plurality of first through-vias 414, a first sealing layer 417, a plurality of second through-vias 423, and a second sealing layer 425. According to one or more embodiments, the semiconductor package 1000A may further include a plurality of connection bumps 433.

The first semiconductor chip 100, the second semiconductor chip 200, and the third semiconductor chip 300 may be bonded and coupled to each other by metal-to-metal bonds and dielectric-to-dielectric bonds. The first semiconductor chip 100, the second semiconductor chip 200, and the third semiconductor chip 300 may include chiplets forming a multi-chip module (MCM). For example, the first semiconductor chip 100 and the second semiconductor chip 200 may be chiplets of logic chips including a central processor (CPU), a graphics processor (GPU), a field programmable gate array (FPGA), a digital signal processor (DSP), an application-specific integrated circuit (ASIC), and at least one third semiconductor chip 300 is a chiplet including an input/output circuit, an analog circuit, a memory circuit, and a serial-parallel conversion circuits for the first semiconductor chip 100 and/or the second semiconductor chip 200.

According to one or more embodiments, the first semiconductor chip 100, the second semiconductor chip 200, and the third semiconductor chip 300 are supplied with power through respective rear surfaces BS1, BS2 and BS3 thereof, so that the congestion of integrated circuits formed in front surfaces FS1, FS2, and FS3 may be reduced. Accordingly, a voltage drop of the integrated circuit may be reduced, and a switching time may be shortened. For example, the first semiconductor chip 100 may be supplied with power through a plurality of first through-vias 414 and a plurality of second through-vias 423 connected to a first rear surface BS1 of the first semiconductor chip 100. The second semiconductor chip 200 may be supplied with power through the at least one third semiconductor chip 300 disposed on a second rear surface BS2 of the second semiconductor chip 200. The at least one third semiconductor chip 300 may be supplied with power through a plurality of connection bumps 433 connected to a third rear surface BS3 of the third semiconductor chip 300. In this case, a first planar area of the first semiconductor chip 100 may be greater than a second planar area of the second semiconductor chip 200, and the second planar area of the second semiconductor chip 200 may be greater than a third planar area of the at least one third semiconductor chip 300.

The first semiconductor chip 100 includes a first substrate 110, a first integrated circuit layer 120, a plurality of first through-electrodes 141 and 142, a plurality of first rear pads 151 and 152, and a first passivation layer 155.

The first substrate 110 may have a front surface FS1 on which an integrated circuit is formed, and a rear surface BS1 opposite thereto. The front surface FS1 and the rear surface BS1 may be referred to as a front surface FS1 and a rear surface BS1 of the first semiconductor chip 100, respectively. The first substrate 110 may be a semiconductor wafer including a semiconductor element such as silicon and germanium, or a compound semiconductor such as silicon carbide (SiC), gallium arsenide (GaAs), indium arsenide (InAs), and indium phosphide (InP). The first substrate 110 may include a conductive region 112 and an isolation region 111 formed on the front surface FS1. The conductive region 112 may be, for example, a well doped with an impurity element or a structure doped with an impurity element. The isolation region 111 is a device isolation structure having a shallow trench isolation (STI) structure and may include silicon oxide. An insulating protective layer 113 may be disposed on the rear surface BS1 of the first substrate 110. The insulating protective layer 113 may include, for example, silicon oxide (SiO), silicon nitride (SiN), silicon carbide (SiC), silicon oxynitride (SiON), or silicon carbonitride (SiCN).

The first integrated circuit layer 120 may be disposed on the front surface FS1 of the first substrate 110 on which the conductive region 112 is formed. The first integrated circuit layer 120 may include individual elements ID, an interlayer insulating layer 121, and a wiring structure 125.

The individual elements ID may be disposed on the front surface FS1 of the first substrate 110. The individual elements ID may be electrically connected to the conductive region 112. The individual elements ID may include, for example, FETs such as a planar FET, a FinFET and the like, memory elements such as a flash memory, a DRAM, an SRAM, an EEPROM, a PRAM, an MRAM, a FeRAM, a RRAM and the like, logic elements such as AND, OR, NOT, and the like, and various active and/or passive devices such as system LSI, CIS, MEMS, and the like.

The interlayer insulating layer 121 may be formed to cover the individual elements ID and the wiring structure 125, and may electrically separate the individual elements ID disposed on the first substrate 110. The interlayer insulating layer 121 may include Flowable oxide (FOX), Tonen SilaZen (TOSZ), undoped Silica Glass (USG), Borosilica Glass (BSG), PhosphoSilaca Glass (PSG), BoroPhosphoSilica Glass (BPSG), Plasma Enhanced Tetra Ethyl Ortho Silicate (PETEOS), Fluoride Silicate Glass (FSG), High Density Plasma (HDP) oxide, Plasma Enhanced Oxide (PEOX), Flowable CVD (FCVD) oxide, or a combination thereof. At least a portion of the interlayer insulating layer 121 surrounding the wiring structure 125 may be comprised of a low dielectric layer. The interlayer insulating layer 121 may be formed using a chemical vapor deposition (CVD) process, a flowable CVD process, or a spin coating process.

The wiring structure 125 may be formed in a multilayer structure including a plurality of wiring patterns and a plurality of vias including, for example, aluminum (Al), gold (Au), cobalt (Co), copper (Cu), nickel (Ni), lead (Pb), tantalum (Ta), tellurium (Te), and titanium (Ti), tungsten (W), or a combination thereof. A barrier film (not shown) including titanium (Ti), titanium nitride (TiN), tantalum (Ta), or tantalum nitride (TaN) may be disposed between the wiring pattern or/and the via and the interlayer insulating layer 121. The wiring structure 125 may be electrically connected to the individual elements ID by an interconnector 123 (e.g., a contact plug). The wiring structure 125 may be combined with individual elements ID to form a first integrated circuit IC1. The first integrated circuit IC1 may transmit and receive input/output signals, a power signal, and a ground signal through the plurality of first through-electrodes 141 and 142.

The plurality of first through-electrodes 141 and 142 may penetrate through the first substrate 110 and may electrically connect the first integrated circuit IC1 and the plurality of first rear pads 151 and 152. The plurality of first through-electrodes 141 and 142 may include a first group of first through-electrodes 141 and a second group of first through-electrodes 142. The first group of first through-electrodes 141 may be configured to transmit input and output signals of the first integrated circuit IC1. The second group of first through-electrodes 142 may be configured to transmit a power signal and/or a ground signal of the first integrated circuit IC1. In one or more embodiments, the first semiconductor chip 100 may be configured to receive power and ground signals through the second group of first through-electrodes 142, a plurality of first through-vias 414, and a plurality of second through-vias 423. The input/output signals may include a data signal transmitted from the first integrated circuit IC1 and a data signal transmitted to the first integrated circuit IC1 from the outside.

Each of the plurality of first through-electrodes 141 and 142 is illustrated in the form of a single post, but embodiments are not limited thereto. For example, the plurality of first through-electrodes 141 and 142 may be provided in a form in which two or more conductive vias are connected to each other. Furthermore, in FIG. 2B, the second group of first through-electrodes 142 is configured to apply a potential to the conductive region 112 through the wiring structure 125, but embodiments are not limited thereto. According to one or more embodiments, the second group of first through-electrodes 142 may be connected to the conductive region 112 through a power rail or the like embedded on a level lower than the front surface FS1 of the first substrate 110, or may extend in the vertical direction (Z-direction) within the first substrate 110 and be directly connected to the conductive region 112.

The plurality of first rear pads 151 and 152 may be disposed on the rear surface BS1 of the first substrate 110. The plurality of first rear pads 151 and 152 may include a first group of first rear pads 151 and a second group of first rear pads 152. The first group of first rear pads 151 may be electrically connected to the first group of first through-electrodes 141. The second group of first rear pads 152 may be electrically connected to the second group of first through-electrodes 142. The plurality of first rear pads 151 and 152 may include at least one of copper (Cu), nickel (Ni), gold (Au), silver (Ag), titanium (Ti), titanium nitride (TiN), tantalum (Ta), and tantalum nitride (TaN).

The first passivation layer 155 may be formed to cover at least a portion of each of the plurality of first rear pads 151 and 152. The first passivation layer 155 may form a surface supplied to dielectric-to-dielectric bonds between the plurality of first rear pads 151 and 152. For example, the first passivation layer 155 may include at least one of silicon oxide (SiO), silicon nitride (SiN), and silicon carbonitride (SiCN).

The second semiconductor chip 200 may be disposed on the rear surface BS1 of the first semiconductor chip 100. The second semiconductor chip 200 may include a second substrate 210, a second integrated circuit layer 220, a plurality of first front pads 233, a plurality of second through-electrodes 241 and 242, a plurality of second rear pads 251 and 252, and a second passivation layer 255.

Since the second semiconductor chip 200 includes components that are substantially identical to or similar to those of the first semiconductor chip 100, these components are referred to using identical or similar shapes, terms, and/or reference signs, and overlapping portions thereof are briefly explained below. For example, the second substrate 210, the second integrated circuit layer 220, the plurality of second through-electrodes 241 and 242, the plurality of second rear pads 251 and 252, and the second passivation layer 255 may be understood as having characteristics substantially identical to or similar to the first substrate 110, the first integrated circuit layer 120, the plurality of first through-electrodes 141 and 142, the plurality of first rear pads 151 and 152, and the first passivation layer 155 of the above-described first semiconductor chip 100.

The second substrate 210 may have a front surface FS2 on which an integrated circuit is formed and a rear surface BS2 opposite to the front surface FS2. The front surface FS2 and the rear surface BS2 may be referred to as a front surface FS2 and a rear surface BS2 of the second semiconductor chip 100, respectively. An insulating protective layer 213 may be disposed on the rear surface BS2 of the second substrate 210.

The second integrated circuit layer 220 may be disposed on the front surface FS2 of the second substrate 210. The second integrated circuit layer 220 may include individual elements ID, an interlayer insulating layer 221, and a wiring structure 225. The interconnection structure 225 may be combined with the individual elements ID to form a second integrated circuit IC2. The second integrated circuit IC2 may transmit and receive input/output signals, a power signal, and a ground signal through the plurality of second through-electrodes 241 and 242.

The plurality of first front pads 233 may be disposed on the front surface FS2 of the second substrate 210. The plurality of first front pads 233 may be electrically connected to the wiring structure 225 of the second integrated circuit layer 220. The plurality of first front pads 233 may be in contact with the plurality of first rear pads 151 and 152 of the first semiconductor chip 100. The plurality of first front pads 233 may include a conductive material that may be bonded and combined with the plurality of first rear pads 151 and 152, for example, at least one of copper (Cu), nickel (Ni), gold (Au), silver (Ag), titanium (Ti), titanium nitride (TiN), tantalum (Ta), and tantalum nitride (TaN).

The plurality of first front pads 233 may include a base portion 231 connected to the second integrated circuit IC2, and a bonding portion 232 between the base portion 231 and the first group of first rear pads 151. A height of the bonding portion 232 may be greater than a height of the base portion 231. The base portion 231 may be a connection terminal (for example, an aluminum pad) of a bare chip, but embodiments are not limited thereto. According to one or more embodiments, the base portion 231 may be a connection structure (e.g., a copper pad) formed on a connection terminal of the bare chip. For example, the bonding portion 232 may include at least one of copper (Cu), nickel (Ni), gold (Au), silver (Ag), titanium (Ti), titanium nitride (TiN), tantalum (Ta), and tantalum nitride (TaN).

The plurality of second through-electrodes 241 and 242 may penetrate through the second substrate 210, and may electrically connect the second integrated circuit IC2 and the plurality of second rear pads 251 and 252. The plurality of second through-electrodes 241 and 242 may include a first group of second through-electrodes 241 and a second group of second through-electrodes 242. The first group of second through-electrodes 241 may be configured to transmit input/output signals of the second integrated circuit (IC2). The second group of second through-electrodes 242 may be configured to transmit a power signal and/or a ground signal of the second integrated circuit IC2. In one or more embodiments, the second semiconductor chip 200 may be configured to receive a power signal and a ground signal through the second group of second through-electrodes 242 and the at least one third semiconductor chip 300.

The plurality of second rear pads 251 and 252 may be disposed on a rear surface BS2 of the second substrate 210. The plurality of second rear pads 251 and 252 may include a first group of second rear pads 251 and a second group of second rear pads 252. The first group of second rear pads 251 may be electrically connected to the first group of second through-electrodes 241. The second group of second rear pads 252 may be electrically connected to the second group of second through-electrodes 242.

The second passivation layer 255 may be formed to cover at least a portion of each of the plurality of second rear pads 251 and 252. The second passivation layer 255 may form a surface supplied to dielectric-dielectric bonds between the plurality of second rear pads 251 and 252. For example, the second passivation layer 255 may include at least one of silicon oxide (SiO), silicon nitride (SiN), and silicon carbonitride (SiCN).

At least one third semiconductor chip 300 may be disposed on the rear surface BS2 of the second semiconductor chip 200. At least one third semiconductor chip 300 may include a third substrate 310, a third integrated circuit layer 320, a plurality of second front pads 333, a plurality of third through-electrodes 341, 342a and 342b, a plurality of third rear pads 351 and 352, and a third passivation layer 335.

Since the third semiconductor chip 300 includes components that are substantially identical to or similar to those of the first semiconductor chip 100 and the second semiconductor chip 200, these components are referred to using identical or similar shapes, terms, and/or reference signs, and overlapping portions thereof are briefly explained below. For example, the third substrate 310, the third integrated circuit layer 320, the plurality of second front pads 333, the plurality of third through-electrodes 341, 342a and 342b, the plurality of third rear pads 351 and 352, and the third passivation layer 335 may be understood as having characteristics substantially identical to or similar to the components of the first semiconductor chip 100 and the second semiconductor chip 200 described above.

The third substrate 310 may have a front surface FS3 on which an integrated circuit is formed and a rear surface BS3 opposite to the front surface FS3. The front surface FS3 and the rear surface BS3 may be referred to as a front surface FS3 and a rear surface BS3 of the third semiconductor chip 300, respectively. An insulating protective layer 313 may be disposed on the rear surface BS3 of the third substrate 310.

The third integrated circuit layer 320 may be disposed on the front surface FS3 of the third substrate 310. The third integrated circuit layer 320 may include a third integrated circuit IC3 in which individual elements and a wiring structure are combined. The third integrated circuit IC3 may transmit and receive input/output signals, a power signal, and a ground signal through the plurality of third through-electrodes 341, 342a and 342b.

The plurality of second front pads 333 may be disposed on the front surface FS3 of the third substrate 310. The plurality of second front pads 333 may be electrically connected to the third integrated circuit IC3. The plurality of second front pads 333 may be in contact with the plurality of second rear pads 251 and 252 of the second semiconductor chip 200. The plurality of second front pads 333 may include a conductive material that may be bonded and combined with the plurality of second rear pads 251 and 252, for example, at least one of copper (Cu), nickel (Ni), gold (Au), silver (Ag), titanium (Ti), titanium nitride (TiN), tantalum (Ta), and tantalum nitride (TaN).

The plurality of third through-electrodes 341, 342a and 342b may penetrate through the third substrate 310, and may electrically connect the third integrated circuit IC3 and the plurality of third rear pads 351 and 352. The plurality of third through-electrodes 341, 342a and 342b may include a first group of third through-electrodes 341 and a second group of third through-electrodes 342a and 342b. The first group of third through-electrodes 341 may be configured to transmit input/output signals of the third integrated circuit IC3. The second group of third through-electrodes 342a and 342b may be configured to transmit a power signal and/or a ground signal of the second integrated circuit IC2 and the third integrated circuit IC3.

In one or more embodiments, the second group of third through-electrodes 342a and 342b may include a first power through-electrode 342a and a second power through-electrode 342b. The third semiconductor chip 300 may be configured to receive a power signal and/or a ground signal through the first power through-electrode 342a. The second semiconductor chip 200 may be configured to receive a power signal and/or a ground signal through the second power through-electrode 342b and the second group of through-electrodes 242. The second power through-electrode 342b is illustrated in a single post form for connecting the plurality of second front pads 333 to the second group of third rear pads 352, but embodiments are not limited thereto, and, for example, the second power through-electrode 342b may be provided in a form in which two or more conductive vias are connected, or in a form in which at least one end thereof may be connected to the pads 333 and 352 through a multilayer wiring.

In one or more embodiments, at least one (300B) of a plurality of third semiconductor chips 300A, 300B and 300C) (hereinafter, referred to as ‘a fourth semiconductor chip’) may include only second power through-electrodes 342b. For example, a fourth semiconductor chip 300B may include a fourth integrated circuit layer 320′ on which a power supply circuit for supplying power to the second semiconductor chip 200 is formed. According to one or more embodiments, the fourth integrated circuit layer 320′ may not include individual elements, unlike the first to third integrated circuit layers 120, 220 and 320. According to one or more embodiments, the second power through-electrodes 342b of the fourth semiconductor chip 300B has a greater maximum diameter d2 than a maximum diameter d1 of each of the plurality of first through-electrodes 141 and 142, the plurality of second through-electrodes 241 and 242, and the plurality of third through-electrodes 341, 342a and 342b in a horizontal directions (X-direction and Y-direction). The maximum diameter d2 of the second power through-electrodes 342b may be less than a maximum diameter D2 of the plurality of second through-vias 423, and may be less than or equal to a maximum diameter D1 of the plurality of first through-vias 414 in the horizontal directions (X-direction and Y-direction).

The fourth semiconductor chip 300B may be understood as including components and features identical to or similar to the at least one third semiconductor chip 300 described above, except for the description of the fourth integrated circuit layer 320′ and the second power through-electrodes 342b.

The plurality of third rear pads 351 and 352 may be disposed on the rear surface BS3 of the third substrate 310. The plurality of third rear pads 351 and 352 may include a first group of third rear pads 351 and a second group of third rear pads 352. The first group of third rear pads 351 may be electrically connected to the first group of third through-electrodes 341. The second group of third rear pads 352 may be electrically connected to the second group of third through-electrodes 342a and 342b.

The third passivation layer 335 may be formed to cover at least a portion of each of the plurality of second front pads 333. The third passivation layer 335 may form a surface supplied to dielectric-to-dielectric bonds between the plurality of second front pads 333. The third passivation layer 335 may be bonded and combined with the second passivation layer 255. For example, the third passivation layer 335 may include at least one of silicon oxide (SiO), silicon nitride (SiN), and silicon carbonitride (SiCN).

The plurality of first through-vias 414 may be disposed on at least one side of the second semiconductor chip 200. The plurality of first through-vias 414 may penetrate through the first sealing layer 417, and may be electrically connected to the second group of first rear pads 152. The plurality of first through-vias 414 may include a first pad portion 412, a second pad portion 413, and a first via portion 411. The first pad portion 412 may be disposed in a gap-fill portion 415 of the first sealing layer 417, and may be in contact with the plurality of second through-vias 423. The second pad portion 413 may be disposed in a passivation portion 416 of the first sealing layer 417, and may be in contact with the second group of first rear pads 152. The first via portion 411 may extend in a vertical direction (Z-direction) within the passivation portion 416, and may connect the first pad portion 412 and the second pad portion 413. The plurality of first through-vias 414 may include tungsten (W), titanium (Ti), aluminum (Al), or copper (Cu), and may be formed through a plating process, PVD process, or CVD process.

The first sealing layer 417 may cover the front surface FS2 and a side surface of the second semiconductor chip 200. The first sealing layer 417 may cover at least a portion of each of the plurality of first front pads 233. The first sealing layer 417 may include a gap-fill portion 415 and a passivation portion 416.

The gap-fill portion 415 may surround a side surface of the second semiconductor chip 200 and a first portion of each side surface of the plurality of first front pads 233. Furthermore, the gap-fill portion 415 may surround a side surface of the first pad portion 412 of the plurality of first through-vias 414 and a side surface of the first via portion 411. The passivation portion 416 may be disposed on the gap-fill portion 415, and may surround a second portion of each side surface of the plurality of first front pads 233 and a side surface of the second pad portion 413 of the plurality of first through-vias 414. Here, the first portion of the plurality of first front pads 233 may be defined as including a side surface of the base portion 231 and a portion of a side surface of the bonding portion 232, and the second portion may be defined as including a remaining portion of a side surface of the bonding portion 232.

The passivation portion 416 may be bonded and combined with the first passivation layer 155 of the first semiconductor chip 100. The gap-fill portion 415 and the passivation portion 416 may include, for example, at least one of silicon oxide (SiO), silicon nitride (SiN), and silicon carbonitride (SiCN). The gap-fill portion 415 and the passivation portion 416 may include the same material, but embodiments are not limited thereto.

The plurality of second through-vias 423 may be disposed on at least one side of at least one third semiconductor chip 300. The plurality of second through-vias 423 may penetrate through the second sealing layer 425, and may be electrically connected to the plurality of first through-vias 414. The plurality of second through-vias 423 may include a second via portion 421 and a third pad portion 422. The third pad portion 422 may extend in horizontal directions (X-direction and Y-direction) from the second via portion 421, and may be disposed on one surface of the second sealing layer 425 opposite to the first pad portion 412. The second via portion 421 may extend in the vertical direction (Z-direction) within the second sealing layer 425, and may connect the third pad portion 422 and the first pad portion 412. The plurality of second through-vias 423 may include tungsten (W), titanium (Ti), aluminum (Al), or copper (Cu), and may be formed in a plating process, a PVD process, or a CVD process.

According to one or more embodiments, the second semiconductor chip 200 may be stacked on the first semiconductor chip 100 in a wafer-on-wafer manner, and the third semiconductor chips 300 may be stacked on the second semiconductor chip 200 in a chip-on-wafer manner. Accordingly, the plurality of first through-vias 414 and the plurality of second through-vias 423 may be formed in different shapes. The plurality of second through-vias 423 may have a shape tapered toward the plurality of first through-vias 414 in the vertical direction (Z-direction). A maximum diameter D2 of the plurality of second through-vias 423 may be greater than a maximum diameter D1 of the plurality of first through-vias 414 in the horizontal directions (X-direction and Y-direction). Here, the maximum diameter D2 of the plurality of second through-vias 423 may be understood as a maximum diameter of the second via portion 421, and the maximum diameter D1 of the plurality of first through-vias 414 may be understood as a maximum diameter of the first via portion 411 in the horizontal directions (X-direction and Y-direction).

The second sealing layer 425 may cover the rear surface BS3 and a side surface of the at least one third semiconductor chip 300. The second sealing layer 425 may include a material different from the first sealing layer 417. The second sealing layer 425 may include a polymer resin, for example, a thermosetting resin such as an epoxy resin, and a thermoplastic resin such as polyimide, prepreg in which these resins are impregnated with an inorganic filler, an Ajinomoto Build-up film (ABF), FR-4, BT, an Epoxy Molding Compound (EMC), or the like.

A plurality of connection bumps 433 may be disposed on the plurality of third rear pads 352 and the pad portion 422 of the plurality of second through-vias 423. The plurality of connection bumps 433 may include a pillar portion 431 and a solder portion 432. The pillar portion 431 may include copper (Cu) or an alloy of copper (Cu), and the solder portion 432 may include a low melting point metal, such as tin (Sn) or an alloy including tin (Sn) (e.g., Sn—Ag, or Sn—Ag—Cu). According to one or more embodiments, the plurality of connection bumps 433 may include only the pillar portion 431 or only the solder portion 432.

According to one or more embodiments, the semiconductor package 1000A may further include under bump structures 434 and/or a protective layer 435. The under bump structures 434 may electrically connect the plurality of third rear pads 352 and the plurality of connection bumps 433. The protective layer 435 may cover the under bump structures 434 and the plurality of second through-vias 423, and may expose at least a portion of each of the plurality of connection bumps 433. The protective layer 435 may be formed using photo solder resist, and the like, but embodiments are not limited thereto.

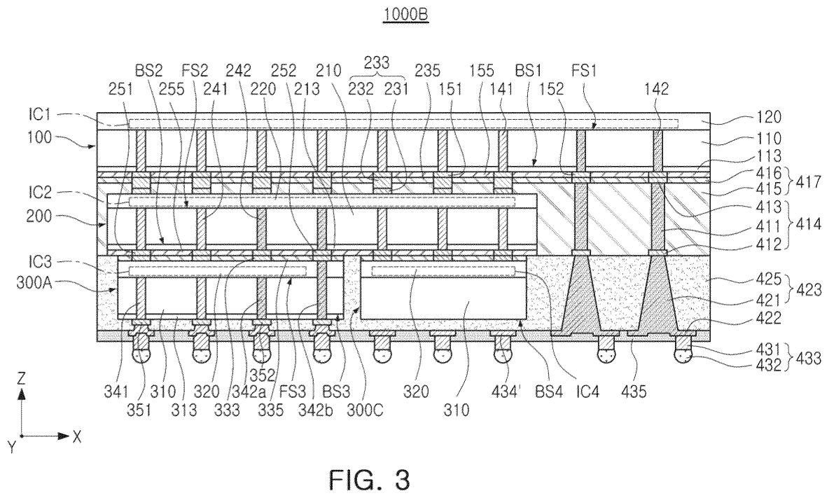

FIG. 3 is a cross-sectional view of a semiconductor package 1000B according to one or more embodiments.

Referring to FIG. 3, the semiconductor package 1000B of one or more embodiments may have the features identical to or similar to those described with reference to FIGS. 1 to 2B, except that at least one semiconductor chip 300C (hereinafter, may be referred to as a ‘fifth semiconductor chip’) of the third semiconductor chips 300A, 300B and 300C does not include a through-electrode.

The fifth semiconductor chip 300C may include an integrated circuit IC4 for interaction with the second semiconductor chip 200. The fifth semiconductor chip 300C may include third front pads 333 electrically connected to the first group of second through-electrodes 241. The fifth semiconductor chip 300C may include a cache memory circuit that provides cache information to the second semiconductor chip 200. A rear surface BS4 of the fifth semiconductor chip 300C may be spaced apart from the plurality of connection bumps 433 by the second sealing layer 425.

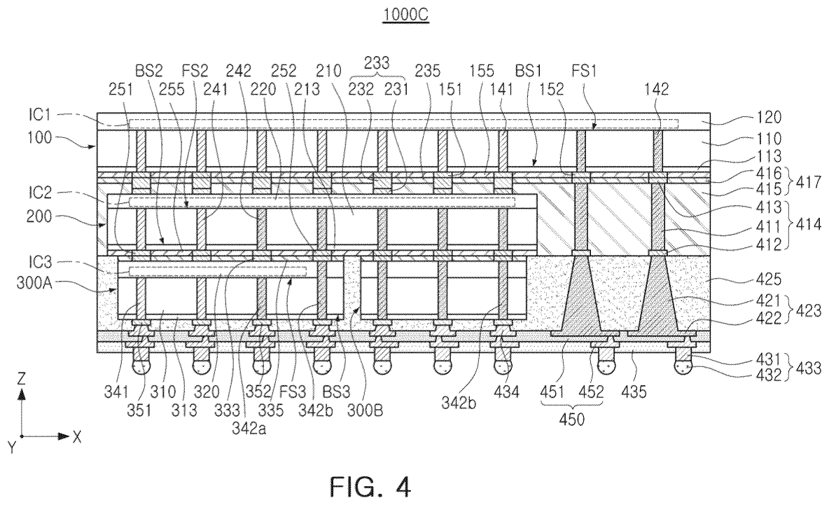

FIG. 4 is a cross-sectional view of a semiconductor package 1000C according to one or more embodiments.

Referring to FIG. 4, the semiconductor package 1000C of one or more embodiments may have the features identical to or similar to those described with reference to FIGS. 1A to 3 except that the semiconductor package 1000C further includes a redistribution structure 450 for redistribution the plurality of third rear pads 351 and 352 and the plurality of second through-vias 423.

The redistribution structure 450 may include an insulating material layer 451 and a redistribution pattern layer 452. The insulating material layer 451 may cover the plurality of third rear pads 351 and 352 and the plurality of second through-vias 423 on the second sealing layer 425. The insulating material layer 451 may be formed using a dielectric material such as silicon oxide, silicon nitride, or silicon oxynitride, or a photosensitive resin such as Photoimageable Dielectric (PID). The insulating material layer 451 may be comprised of a plurality of layers depending on the number of layers of a redistribution pattern layer 512. According to the process, boundaries between at least some of the plurality of insulating material layers 451 may not be clear.

The redistribution pattern layer 452 may be disposed in the insulating material layer 451 and may electrically connect the plurality of third rear pads 351 and 352 and the plurality of second through-vias 423 to the plurality of connection bumps 433. The redistribution pattern layer 452 includes, for example, copper (Cu), aluminum (Al), silver (Ag), tin (Sn), gold (Au), nickel (Ni), lead (Pb), and titanium (Ti), or metal materials including alloys thereof. According to one or more embodiments, the redistribution pattern layer 452 may be formed with a greater number of layers than shown in the drawing.

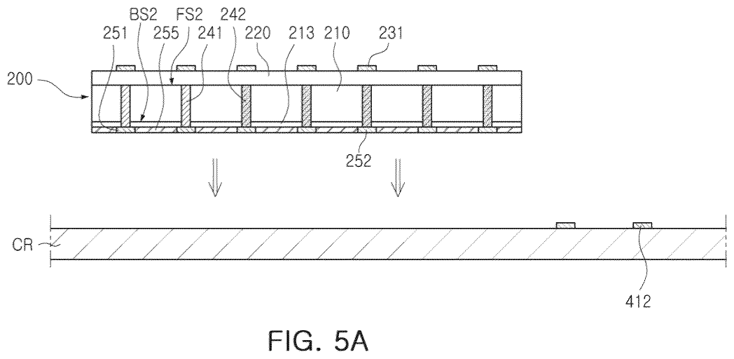

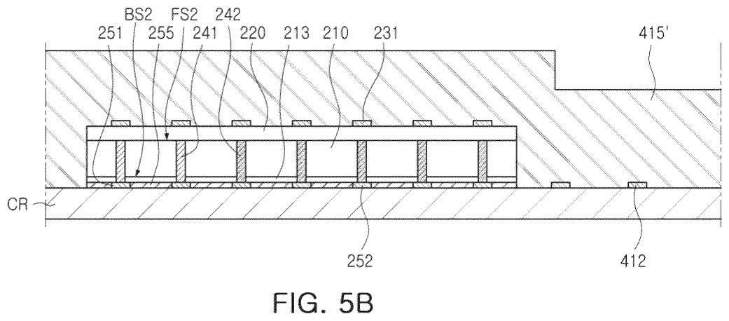

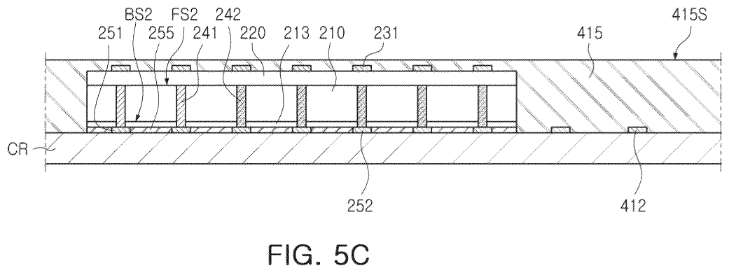

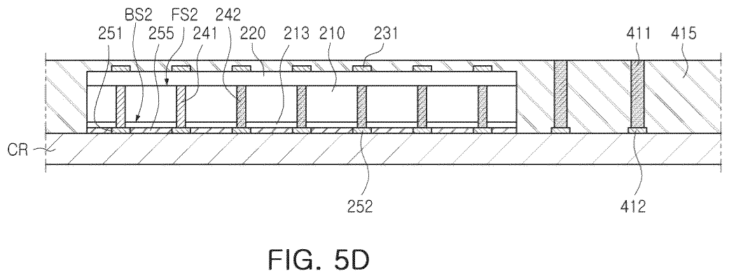

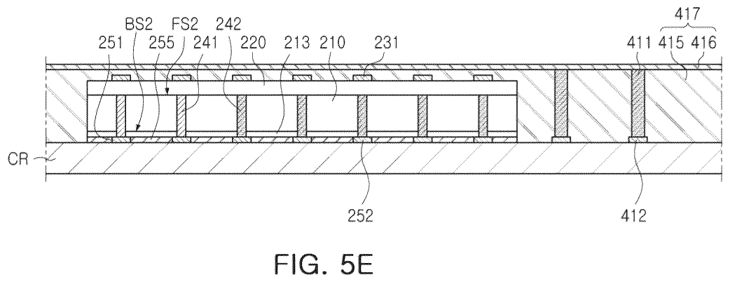

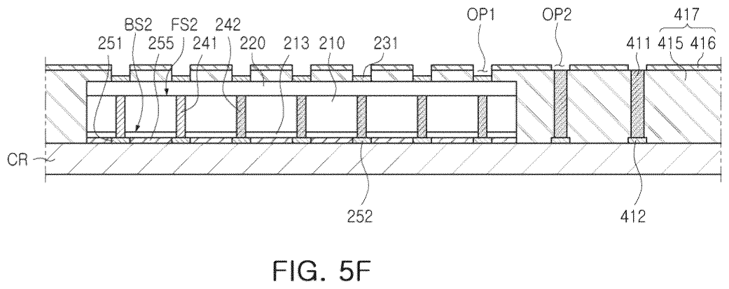

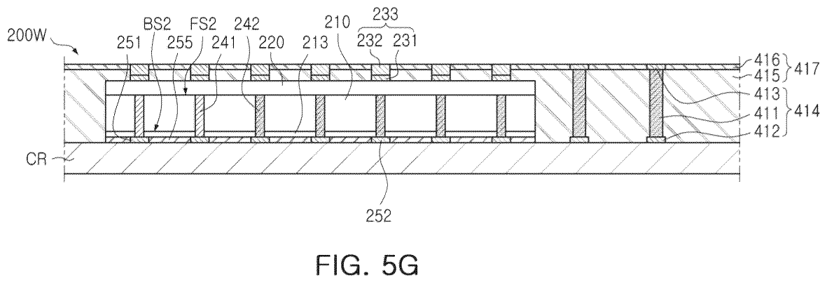

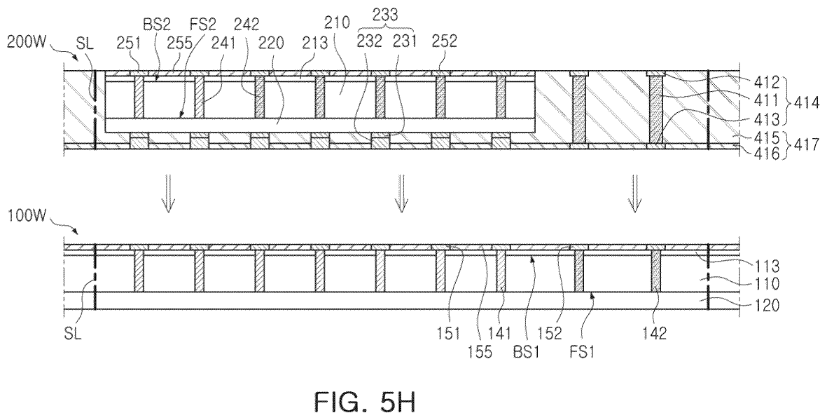

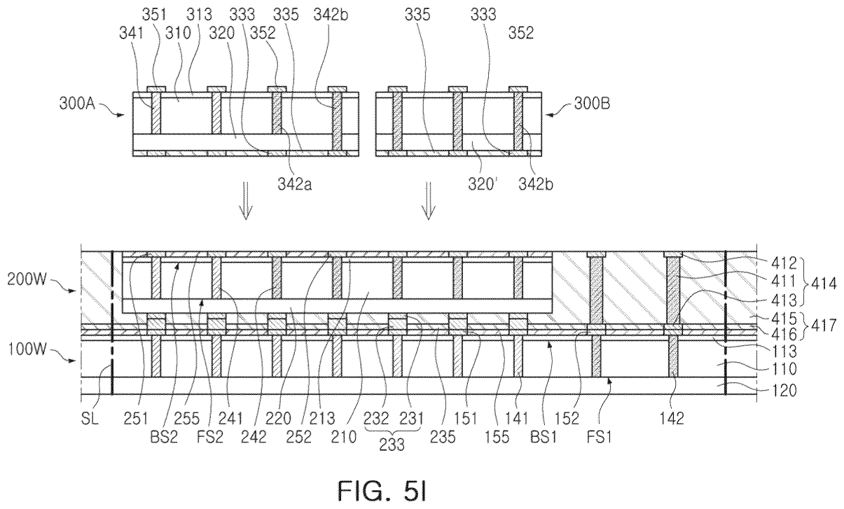

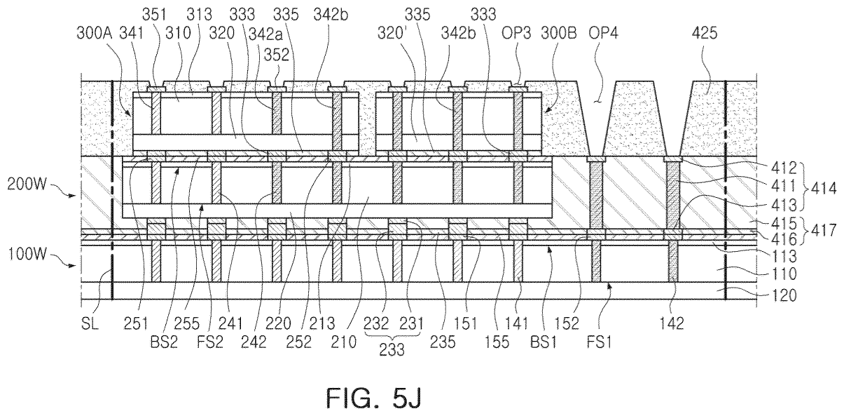

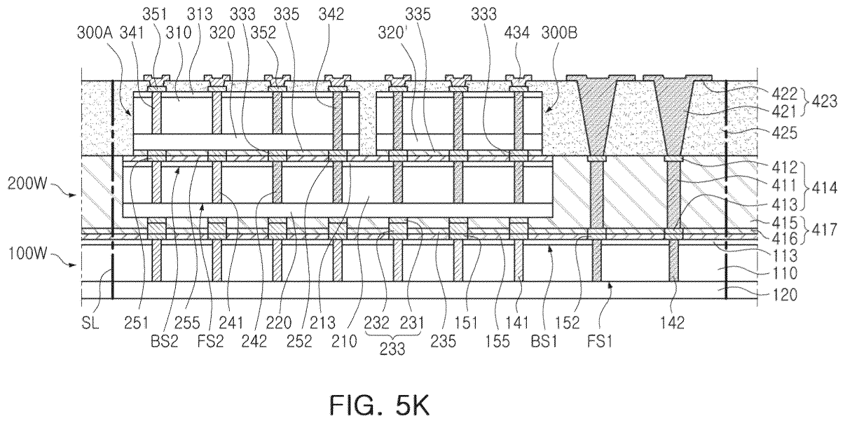

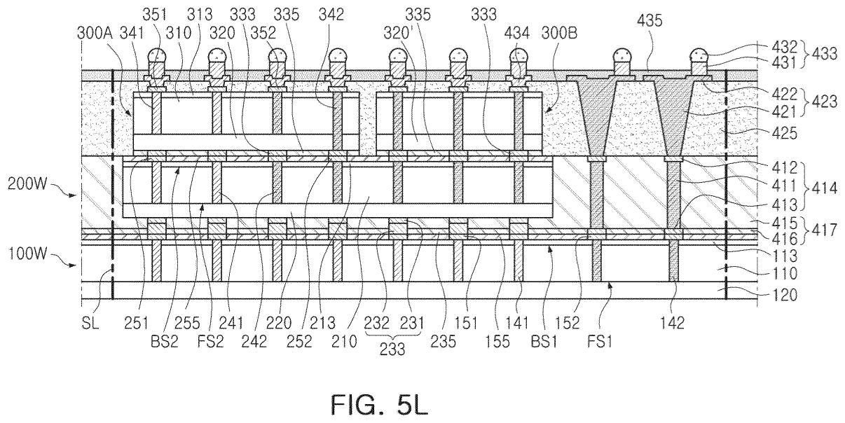

FIGS. 5A to 5L are views illustrating a method of manufacturing the semiconductor package 1000A of FIG. 1.

Referring to FIG. 5A, the second semiconductor chip 200 may be attached to a carrier CR on which the first pad portion 412 is formed. A temporary bonding layer, for example, a silicon oxide layer, may be formed on one surface of the carrier CR in which the first pad portion 412 is formed, but embodiments are not limited thereto. In order to illustrate a manufacturing process of the semiconductor package 1000A illustrated in FIG. 2A, only one unit of the carrier CR is illustrated. For example, the carrier CR may be a carrier wafer of 6 inches, 8 inches, 12 inches, or the like, in which dozens or more of one unit illustrated in the drawing are included. Below, for convenience of explanation, a manufacturing process of a semiconductor package will be explained focusing on one unit illustrated in the drawing.

The first pad portion 412 may be formed using a deposition process and a plating process. For example, the first pad portion 412 may be formed by performing a plating process using a patterned resist layer on a seed layer formed through a PVD process. For example, a seed layer such as titanium (Ti) may be formed between the first pad portion 412 and the carrier CR, but the seed layer may be removed in a subsequent process for metal bonding of the first pad portion 412.

The second semiconductor chip 200 includes a second substrate 210, a second integrated circuit layer 220, a plurality of base portions 231, a plurality of second through-electrodes 241 and 242, a plurality of second rear pads 251 and 252, and a second passivation layer 255. According to one or more embodiments, the second semiconductor chip 200 may be a known good die (KGD) for which testing has been completed. For example, a yield of the semiconductor package may be improved by manufacturing a recombinant wafer in which the second semiconductor chips 200 for which testing has been completed are arranged.

Referring to FIG. 5B, a preliminary sealing layer 415′ covering the second semiconductor chip 200 and the first pad portion 412 may be formed. The preliminary sealing layer 415′ may include silicon oxide (SiO) and may be formed using a PVD process or a CVD process.

Referring to FIG. 5C, a gap-fill portion 415 having a flattening surface 4155 may be formed. The gap-fill portion 415 may be formed by applying a flattening process to an upper portion of the preliminary sealing layer 415′ of FIG. 5B. For example, the gap-fill portion 415 may be formed through a chemical mechanical polishing (CMP) process.

Referring to FIG. 5D, a first via portion 411 may be formed within the gap-fill portion 415. The first via portion 411 may be formed by filling a conductive material, for example, a metal such as copper (Cu), titanium (Ti), or the like, in the gap-fill portion 415 patterned using a photosensitive material layer and a photolithography process. The first via portion 411 may be formed using a deposition process and a plating process. In the drawing, a seed layer covering a lower surface and a side surface of the first via portion 411 may be formed. Through the flattening process, an upper surface of the first via portion 411 and an upper surface of the gap-fill portion 415 may be coplanar with each other.

Referring to FIG. 5E, a passivation portion 416 covering an upper surface of the first via portion 411 and an upper surface of the gap-fill portion 415 may be formed. The passivation portion 416 may include silicon oxide (SiO) and silicon carbonitride (SiCN), and may be formed using a PVD process or a CVD process. The passivation portion 416 may improve the quality of a bonding surface supplied to dielectric-to-dielectric bonds.

Referring to FIG. 5F, a first opening OP1 and a second opening OP2 exposing the second semiconductor chip 200 and the first via portion 411 may be formed. The first opening OP1 and the second opening OP2 may be formed using a photolithography process and an etching process. The first opening OP1 may penetrate through the passivation portion 416 and may extend into the gap-fill portion 415, and may expose the base portions 231 of the second semiconductor chip 200. The second opening OP2 may penetrate through the passivation portion 416 and expose the first via portion 411. A depth of the first opening OP1 may be greater than a depth of the second opening OP2.

Referring to FIG. 5G, a bonding portion 232 and a second pad portion 413 may be formed in the first opening OP1 and the second opening OP2, respectively. The bonding portion 232 and the second pad portion 413 may include copper (Cu) or an alloy thereof and may be formed using a plating process. By applying a flattening process, a recombinant wafer 200W including a second semiconductor chip 200, a plurality of first front pads 233, a plurality of first through-vias 414, and a first sealing layer 417 may be formed.

Referring to FIG. 5H, the recombinant wafer 200W may be attached to a base wafer 100W. The base wafer 100W may be a silicon wafer of a size corresponding to the recombinant wafer 200W, for example, 6 inches, 8 inches, 12 inches, or the like. The base wafer 100W may include a first substrate 110, a first integrated circuit layer 120, a plurality of first through-electrodes 141 and 142, a plurality of first rear pads 151 and 152, and a passivation layer 155. The recombinant wafer 200W may be attached so that the first sealing layer 417 and the first passivation layer 155 of the base wafer 100W face each other. Then, the base wafer 100W and the recombinant wafer 200W may be combined by performing a thermal compression process. A heat compression process may be performed in a thermal atmosphere ranging from about 100° C. to about 300° C. However, a temperature of the thermal atmosphere is not limited to the above-mentioned range and may be variously changed.

Referring to FIG. 5I, a plurality of third semiconductor chips 300A and 300B may be attached to the recombinant wafer 200W. The plurality of third semiconductor chips 300A and 300B may be combined with the recombinant wafer 200W through a thermal compression process. A flattening process may be applied to an upper surface of the recombinant wafer 200W to remove a seed layer of the first pad portion 412.

Referring to FIG. 5J, a second sealing layer 425 may be formed on the recombinant wafer 200W. The second sealing layer 425 may be formed by applying and curing a polymer resin. Then, a third opening OP3 and a fourth opening OP4 may be formed using a visual process. The third opening OP3 may expose the third rear pads 351 and 352 of the third semiconductor chips 300A and 300B. The fourth opening OP4 may penetrate the second sealing layer 425, and may expose the plurality of first through-vias 414. The third opening OP3 and the fourth opening OP4 may be formed using a laser. The third opening OP3 and the fourth opening OP4 may have a shape tapered downwardly in the vertical direction (Z-direction).

Referring to FIG. 5K, under bump structures 434 and a plurality of second through-vias 423 may be formed in the third opening OP3 and the fourth opening OP4, respectively. The under bump structures 434 and the plurality of second through-vias 423 may be formed through a plating process. The plurality of second through-vias 423 may be formed to have a third pad portion 422 extending in the horizontal direction from the second via portion 421. The plurality of second through-vias 423 may have a shape tapered toward the plurality of first through-vias 414 in the vertical direction (Z-direction). A maximum diameter of the plurality of second through-vias 423 may be greater than a maximum diameter of the plurality of first through-vias 414 in the horizontal directions (X-direction and Y-direction). Here, the maximum diameter of the plurality of second through-vias 423 may be understood as a maximum diameter of the second via portion 421, and the maximum diameter of the plurality of first through-vias 414 may be understood as a maximum diameter of the first via portion 411 in the horizontal directions (X-direction and Y-direction).

Referring to FIG. 5L, a plurality of connection bumps 433 and a protective layer 435 may be formed on the under bump structures 434 and the plurality of second through-vias 423. Then, the semiconductor packages may be separated by performing a cutting process along the scribe lane SL.

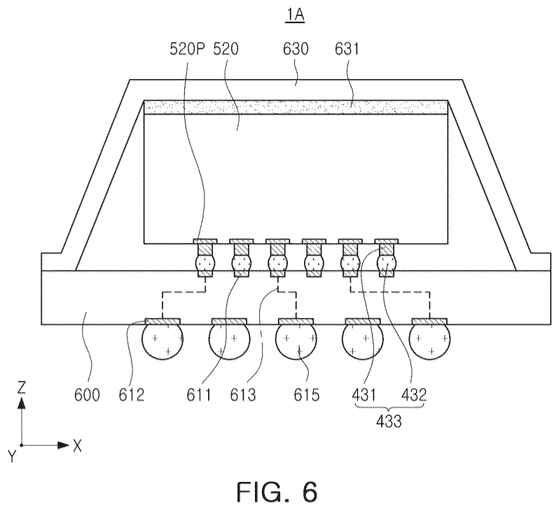

FIG. 6 is a cross-sectional view of a semiconductor package 1A according to one or more embodiments.

Referring to FIG. 6, the semiconductor package 1A of the example embodiment may include a semiconductor chip structure 520, a package substrate 600, and a heat dissipation structure 630. The semiconductor chip structure 520 may be a semiconductor package structure having the characteristics identical to or similar to the semiconductor packages 1000A, 1000B and 1000C described with reference to FIGS. 1 to 4. The semiconductor chip structure 520 may be electrically connected to the package substrate 600 through connection bumps 433 on a connection terminal 520P.

The package substrate 600 is a support substrate on which the semiconductor chip structure 520 is mounted, and may be a substrate for a semiconductor package, such as a printed circuit board (PCB), a ceramic substrate, or a tape wiring board. The package substrate 600 may include a lower pad 612, an upper pad 611, and a wiring circuit 613. A body of the package substrate 600 may include different materials depending on the type of substrate. For example, if the package substrate 600 is a printed circuit board, it may be in a form in which wiring layers are additionally stacked on one surface or both surfaces of a body copper foil laminate or a copper foil laminate. The upper pad 611, the lower pad 612, and the wiring circuit 613 may form an electrical path for connecting a lower surface and an upper surface of the package substrate 600. An external connection bump 615 may be disposed on the lower pad 612. The external connection bump 615 may include tin (Sn), indium (In), bismuth (Bi), antimony (Sb), copper (Cu), silver (Ag), zinc (Zn), lead (Pb), and/or alloys thereof.

The heat dissipation structure 630 may be arranged to cover an upper portion of the semiconductor chip structure 520. The heat dissipation structure 630 may be attached to the package substrate 600 using an adhesive. The heat dissipation structure 630 may include a material having excellent thermal conductivity, for example, aluminum (Al), gold (Au), silver (Ag), copper (Cu), iron (Fe), graphite, and graphene. The heat dissipation structure 630 may have a shape different from that shown in the drawing. For example, the heat dissipation structure 630 may have a shape that covers only an upper surface of the semiconductor chip structure 520. The heat dissipation structure 630 may be attached to an upper portion of the semiconductor chip structure 520 through a heat transfer material layer 631. The heat transfer material layer 631 may include a thermal interface material (TIM), such as a thermally conductive adhesive tape, thermally conductive grease, or thermally conductive adhesive.

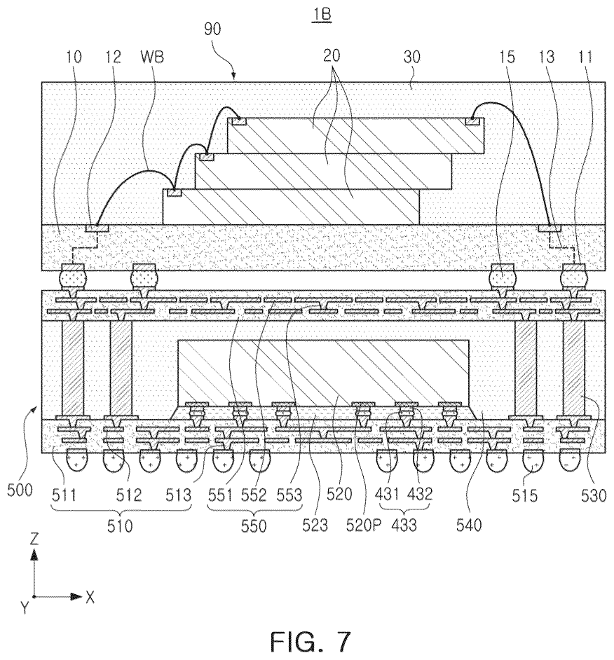

FIG. 7 is a cross-sectional view of a semiconductor package 1B according to one or more embodiments.

Referring to FIG. 7, the semiconductor package 1B of the example embodiment may include a first package 500 and a second package 90.

The first package 500 may include a lower redistribution structure 510, a first semiconductor chip structure 520, an interconnection via 530, a first mold layer 540, an upper redistribution structure 550, and first connection bumps 515.

The lower redistribution structure 510 may include a lower insulating layer 511, lower redistribution layers 512, and lower vias 513. The lower insulating layer 511 may include, for example, prepreg, an Ajinomoto Build-up Film (ABF), FR-4, and BT Photoimageable Dielectric (PID). The lower redistribution layers 512 and the lower vias 513 may include copper (Cu), aluminum (Al), silver (Ag), tin (Sn), gold (Au), nickel (Ni), lead (Pb), titanium (Ti), or a metal material including or an alloy thereof.

The first semiconductor chip structure 520 may be a semiconductor package structure having the characteristics identical to or similar to the semiconductor packages 1000A, 1000B and 1000C described with reference to FIGS. 1 to 4. The first semiconductor chip structure 520 may be electrically connected to the package substrate 600 through the connection bumps 433 on a connection terminal 520P. An underfill layer 523 may be disposed between the first semiconductor chip structure 520 and the lower redistribution structure 510. The underfill layer 523 may include an insulating resin such as, for example, epoxy resin and may protect the connection bumps 433 physically and electrically. The underfill layer 523 may have a capillary underfill (CUF) structure, but embodiments are not limited thereto. According to one or more embodiments, the underfill layer 523 may have a molded underfill (MUF) structure integrated with the first mold layer 540.

The interconnection via 530 may penetrate through the first mold layer 540 and electrically connect the lower redistribution layers 512 and the upper redistribution layers 552. The interconnection via 530 may have a post shape penetrating through the mold layer 540. The interconnection via 530 may include copper (Cu), aluminum (Al), silver (Ag), tin (Sn), gold (Au), nickel (Ni), lead (Pb), titanium (Ti), or a metal material including alloys thereof. The first mold layer 540 may include, for example, ABF, FR-4, BT, and an Epoxy Molding Compound (EMC).

The upper redistribution structure 550 may include an upper insulating layer 551, upper redistribution layers 552, and upper vias 553. Since the upper insulating layer 551, the upper redistribution layers 552, and the upper vias 553 have the characteristics identical to or similar to the lower insulating layer 511, the lower redistribution layers 512, and the lower vias 513 described above, overlapping descriptions thereof will be omitted.

The first external connection bumps 515 may be electrically connected to the lower redistribution layer 512. The first package 500 may be connected to an external device such as a module board or a system board through the first external connection bumps 515. The first external connection bumps 515 may include a low melting point metal, for example, tin (Sn) or an alloy including tin (Sn) (e.g., Sn—Ag—Cu).

The second package 90 may include a wiring board 10, a second semiconductor chip structure 20, and a second mold layer 30. The wiring board 10 may include a lower pad 11, an upper pad 12, and a wiring circuit 13.

The second semiconductor chip structure 20 may be mounted on the wiring board 10 using a wire bonding manner or a flip chip bonding manner. For example, the second semiconductor chip structure 20 may include a plurality of semiconductor chips stacked in a vertical direction, and may be electrically connected to the upper pad 12 of the wiring board 10 by a bonding wire WB. The second semiconductor chip structure 20 may include a different type of semiconductor chip from the first semiconductor chip structure 420. For example, the second semiconductor chip structure 20 may include a plurality of memory chips, and the first semiconductor chip structure 420 may include a logic chip.

The second mold layer 30 may include a material identical to or similar to the first mold layer 540 of the first package 500. The second package 90 may be physically and electrically connected to the first package 500 by a second external connection bump 15. The second external connection bump 15 may include a material identical to or similar to the first external connection bump 515.

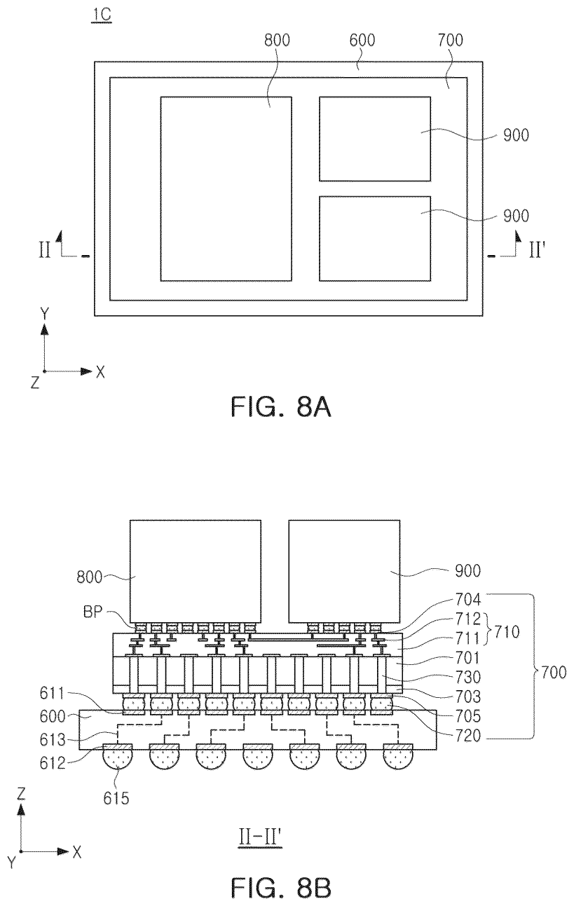

FIG. 8A is a plan view of a semiconductor package 1000C according to one or more embodiments, and FIG. 8B is a cross-sectional view taken along line II-II′ of FIG. 8A.

Referring to FIGS. 8A and 8B, the semiconductor package 1000C of the one or more embodiments may include a package substrate 600, an interposer substrate 700, a first semiconductor chip structure 800, and a second semiconductor chip structure 900. Since the package substrate 600 has the characteristics identical to or similar to those described with reference to FIG. 6, overlapping descriptions thereof will be omitted.

The first semiconductor chip structure 800 may be a semiconductor package structure having the characteristics identical to or similar to the semiconductor packages 1000A, 1000B, and 1000C described with reference to FIGS. 1 to 4.

The second semiconductor chip structure 900 may include a different type of semiconductor chip from the first semiconductor chip structure 800. For example, the second semiconductor chip structure 900 may include a high-capacity memory device such as a high bandwidth memory (HBM).

The interposer substrate 700 may include a semiconductor substrate 701, a lower protective layer 703, a lower pad 705, an interconnection structure 710, a conductive bump 720, and a through-silicon via 730. The first semiconductor chip structure 800 and the second semiconductor chip structure 900 may be electrically connected to each other via the interposer substrate 700.

The semiconductor substrate 701 may be formed of, for example, any one of silicon, organic, plastic, and glass substrates. When the semiconductor substrate 701 is a silicon substrate, the interposer substrate 700 may be referred to as a silicon interposer. Unlike what is illustrated in the drawing, when the semiconductor substrate 701 is an organic substrate, the interposer substrate 700 may be referred to as a panel interposer.

The lower protective layer 703 may be disposed on a lower surface of the semiconductor substrate 701, and the lower pad 705 may be disposed below the lower protective layer 703. The lower pad 705 may be connected to the through-silicon via 730. The interposer substrate 700 may be electrically connected to the package substrate 600 through conductive bumps 720 disposed below the lower pad 705.

The interconnection structure 710 may be disposed on an upper surface of the semiconductor substrate 701, and may include an interlayer insulating layer 711 and a single layer or multilayer wiring structure 712. When the interconnection structure 710 has the multilayer wiring structure, wiring patterns of different layers may be connected to each other through a contact via. The first semiconductor chip structure 800 and the second semiconductor chip structure 900 may be electrically connected to the upper pad 704 through metal bumps BP.

The through-silicon via 730 may extend from an upper surface to a lower surface of the semiconductor substrate 701. Furthermore, the through-silicon via 730 may extend into an interior of the interconnection structure 710, and may be electrically connected to the multilayer wiring structure 712. According to one or more embodiments, the interposer substrate 700 may include only an interconnection structure therein, and may not include the through-silicon via 730.

The interposer substrate 700 may be used to convert or transmit an input electrical signal between the package substrate 600 and the first semiconductor chip structure 800 or the second semiconductor chip structure 900. Accordingly, the interposer substrate 700 may not include devices such as active devices or passive devices. Furthermore, according to one or more embodiments, the interconnection structure 710 may be disposed below the through-silicon via 730. For example, a positional relationship between the interconnection structure 710 and the through-silicon via 730 may be relative.

Embodiments are not limited to the above-described example embodiments and the accompanying drawings but is defined by the appended claims and their equivalents. Therefore, those of ordinary skill in the art may make various replacements, modifications, or changes without departing from the scope of the present disclosure defined by the appended claims, and these replacements, modifications, or changes should be construed as being included in the scope of the present disclosure.

What is claimed is:

1. A semiconductor package, comprising:
a first semiconductor chip comprising a first integrated circuit on a first front surface, a plurality of first rear pads on a first rear surface opposite to the first front surface, and a plurality of first through-electrodes electrically connecting the first integrated circuit and the plurality of first rear pads, the plurality of first rear pads comprising a first group of first rear pads and a second group of first rear pads;
a second semiconductor chip comprising a second integrated circuit on a second front surface facing the first rear surface of the first semiconductor chip, a plurality of first front pads electrically connected to the second integrated circuit and in contact with the first group of first rear pads, a plurality of second rear pads on a second rear surface opposite to the second front surface, and a plurality of second through-electrodes electrically connecting the second integrated circuit and the plurality of second rear pads;
a first sealing layer on the second front surface and a side surface of the second semiconductor chip;
at least one third semiconductor chip comprising a third integrated circuit on a third front surface facing the second rear surface of the second semiconductor chip, a plurality of second front pads electrically connected to the third integrated circuit and in contact with the plurality of second rear pads, a plurality of third rear pads on a third rear surface opposite to the third front surface, and a plurality of third through-electrodes electrically connecting the third integrated circuit and the plurality of third rear pads;
a second sealing layer on the third rear surface and a side surface of the at least one third semiconductor chip;
a plurality of first through-vias penetrating through the first sealing layer and electrically connected to the second group of first rear pads;
a plurality of second through-vias penetrating through the second sealing layer, electrically connected to the plurality of first through-vias, the plurality of second through-vias having a shape tapered toward the plurality of first through-vias; and
a plurality of connection bumps on the second sealing layer, and electrically connected to the plurality of third rear pads and the plurality of second through-vias,
wherein a maximum diameter of the plurality of second through-vias is greater than a maximum diameter of the plurality of first through-vias in a horizontal direction.

2. The semiconductor package of claim 1, wherein the plurality of first through-vias comprises:
a first pad portion in contact with the plurality of second through-vias;
a second pad portion in contact with the second group of first rear pads; and
a via portion connecting the first pad portion and the second pad portion.

3. The semiconductor package of claim 2, wherein the first sealing layer comprises:
a gap-fill portion on the side surface of the second semiconductor chip and a first portion of a side surface of each of the plurality of first front pads; and
a passivation portion on a second portion of the side surface of each of the plurality of first front pads on the gap-fill portion,
wherein the gap-fill portion is on a side surface of the first pad portion and a side surface of the via portion, and
wherein the passivation portion is on a side surface of the second pad portion.

4. The semiconductor package of claim 1, wherein the plurality of second through-vias comprise:
a via portion in the second sealing layer; and
a pad portion extending in the horizontal direction from the via portion and in contact with the plurality of connection bumps.

5. The semiconductor package of claim 1, wherein the plurality of first front pads comprise:
a base portion connected to the second integrated circuit; and
a bonding portion between the base portion and the first group of first rear pads, and
wherein a height of the bonding portion is greater than a height of the base portion in a vertical direction.

6. The semiconductor package of claim 5, wherein the first sealing layer comprises:
a gap-fill portion on the side surface of the second semiconductor chip and a first portion of a side surface of each of the plurality of first front pads; and
a passivation portion on a second portion of the side surface of each of the plurality of first front pads on the gap-fill portion,
wherein the first portion comprises a side surface of the base portion and a portion of a side surface of the bonding portion, and
wherein the second portion comprises a remaining portion of the side surface of the bonding portion.

7. The semiconductor package of claim 1, wherein the plurality of first through-electrodes comprise:
a first group of first through-electrodes connected to the first group of first rear pads; and
a second group of first through-electrodes connected to the second group of first rear pads,
wherein the first group of first through-electrodes is configured to transmit input/output signals of the first integrated circuit, and
wherein the second group of first through-electrodes is configured to transmit a power signal and a ground signal of the first integrated circuit.

8. The semiconductor package of claim 1, wherein the plurality of second through-electrodes comprise a first group of second through-electrodes and a second group of second through-electrodes,
wherein the first group of second through-electrodes is configured to transmit input/output signals of the second integrated circuit, and
wherein the second group of second through-electrodes is configured to transmit a power signal and a ground signal of the second integrated circuit.

9. The semiconductor package of claim 8, further comprising:
a fourth semiconductor chip on the second rear surface of the second semiconductor chip and comprising power through-electrodes connected to the second group of second through-electrodes.

10. The semiconductor package of claim 9, wherein a maximum diameter of the power through-electrodes is greater than a maximum diameter of the plurality of first through-electrodes, a maximum diameter of the plurality of second through-electrodes, and a maximum diameter of the plurality of third through-electrodes in the horizontal direction.

11. The semiconductor package of claim 8, further comprising:
a fifth semiconductor chip comprising a plurality of front pads in contact with a first group of second rear pads connected to the first group of second through-electrodes among the plurality of second rear pads,
wherein the second sealing layer is between a rear surface of the fifth semiconductor chip and the plurality of connection bumps.

12. The semiconductor package of claim 1, wherein the plurality of third through-electrodes comprises a first group of third through-electrodes and a second group of third through-electrodes,
wherein the first group of third through-electrodes is configured to transmit input/output signals of the third integrated circuit, and
wherein the second group of third through-electrodes is configured to transmit a power signal and a ground signal of the third integrated circuit.

13. The semiconductor package of claim 1, further comprising:
a redistribution structure comprising an insulating material layer on the plurality of third rear pads and the plurality of second through-vias on the second sealing layer; and
a redistribution pattern layer in the insulating material layer and electrically connecting the plurality of third rear pads and the plurality of second through-vias to the plurality of connection bumps.

14. The semiconductor package of claim 1, further comprising:
under bump structures between the plurality of third rear pads and the plurality of connection bumps; and
a protective layer on the under bump structures, the plurality of second through-vias, and at least a portion of each of the plurality of connection bumps.

15. A semiconductor package, comprising:
a first semiconductor chip comprising a first substrate having a first front surface and a first rear surface opposite to each other, a plurality of first rear pads on the first rear surface, a first passivation layer on at least a portion of each of the plurality of first rear pads, and a plurality of first through-electrodes penetrating through the first substrate and electrically connected to the plurality of first rear pads;
a second semiconductor chip comprising a second substrate having a second front surface and a second rear surface opposite to each other, a plurality of first front pads on the second front surface and in contact with the plurality of first rear pads, a plurality of second rear pads on the second rear surface, a second passivation layer on at least a portion of each of the plurality of second rear pads, and a plurality of second through-electrodes penetrating through the second substrate and electrically connected to the plurality of second rear pads;
a first sealing layer comprising a gap-fill portion on a side surface of the second semiconductor chip and at least a portion of each of the plurality of first front pads, and a passivation portion on the gap-fill portion and in contact with the first passivation layer;
at least one third semiconductor chip comprising a third substrate having a third front surface and a third rear surface opposite to each other, a plurality of second front pads on the third front surface and in contact with the plurality of second rear pads, a third passivation layer on at least a portion of each of the plurality of second front pads and in contact with the second passivation layer, a plurality of third rear pads on the third rear surface, and a plurality of third through-electrodes penetrating through the third substrate and electrically connected to the plurality of third rear pads;
a second sealing layer on a side surface of the at least one third semiconductor chip, and on at least a portion of each of the plurality of third rear pads;
a plurality of first through-vias penetrating through the first sealing layer and electrically connected to at least some of the plurality of first rear pads;
a plurality of second through-vias penetrating through the second sealing layer and electrically connected to the plurality of first through-vias; and
a plurality of connection bumps on the plurality of third rear pads and the plurality of second through-vias,
wherein a material of the first sealing layer is different from a material of the second sealing layer.

16. The semiconductor package of claim 15, wherein the first sealing layer comprises at least one of silicon oxide (SiO), silicon nitride (SiN), and silicon carbonitride (SiCN), and
wherein the second sealing layer comprises a polymer resin.

17. The semiconductor package of claim 15, wherein the plurality of first through-vias comprises a first pad portion in the gap-fill portion, a second pad portion in the passivation portion, and a first via portion extending in a vertical direction within the gap-fill portion and connecting the first pad portion and the second pad portion, and
wherein the plurality of second through-vias comprises a third pad portion on one surface of the second sealing layer opposite to the first pad portion, and a second via portion extending in the vertical direction within the second sealing layer and connecting the third pad portion and the first pad portion.

18. The semiconductor package of claim 15, wherein a first planar area of the first semiconductor chip is greater than a second planar area of the second semiconductor chip, and
wherein the second planar area of the second semiconductor chip is greater than a third planar area of the at least one third semiconductor chip.

19. A semiconductor package, comprising:
a first semiconductor chip comprising a plurality of first rear pads, and a plurality of first through-electrodes electrically connected to the plurality of first rear pads;
a second semiconductor chip comprising a plurality of first front pads in contact with the plurality of first rear pads, a plurality of second rear pads, and a plurality of second through-electrodes electrically connected to the plurality of second rear pads;
at least one third semiconductor chip comprising a plurality of second front pads in contact with the plurality of second rear pads, a plurality of third rear pads, and a plurality of third through-electrodes electrically connected to the plurality of third rear pads;
a plurality of first through-vias on at least one side of the second semiconductor chip and electrically connected to at least some of the plurality of first rear pads;
a plurality of second through-vias on at least one side of the at least one third semiconductor chip and electrically connected to the plurality of first through-vias; and
a plurality of connection bumps on the plurality of third rear pads and the plurality of second through-vias,
wherein the first semiconductor chip is configured to receive power through the plurality of first through-vias and the plurality of second through-vias, and
wherein the second semiconductor chip is configured to receive power through the plurality of third through-electrodes of the at least one third semiconductor chip.

20. The semiconductor package of claim 19, wherein a first maximum diameter of the plurality of first through-vias is less than a second maximum diameter of the plurality of second through-vias in a horizontal direction, and
wherein a third maximum diameter of the plurality of third through-electrodes is less than or equal the first maximum diameter of the plurality of first through-vias in the horizontal direction.
